(19) United States
(12) Patent Application Publication
(10) Pub. No.: US 2021/0157181 A1
(43) Pub. Date: May 27, 2021

(54) SEE-THROUGH, TOUCH-SENSITIVE DISPLAYS

(71) Applicant: APPLESTONE MEAT COMPANY LLC, Stone Ridge, NY (US)

(72) Inventors: Douglas R. Adams, Pepperell, MA (US); Nicholas E. Holsman, Waltham, MA (US)

(21) Appl. No.: 17/105,271

(22) Filed: Nov. 25, 2020

Related U.S. Application Data
(60) Provisional application No. 62/940,825, filed on Nov. 26, 2019.

(51) Int. Cl. G02F 1/137; G02F 1/1333; G02F 1/13363; G02F 1/1334; G07F 9/00

(52) U.S. Cl. CPC G02F 1/137; G02F 1/13338; G02F 1/13363; H01L 27/3232; G07F 9/00; G02F 2203/01; G02F 2413/01; G02F 1/1334

(57) ABSTRACT

See-through, touch-sensitive displays are provided. More particularly, in some embodiments, apparatuses are provided, comprising: a controllable transmittance film; a transparent display panel; a clear panel; a touch sensitive overlay; and a hardware processor coupled to the controllable transmittance film, the transparent display panel, and the touch sensitive overlay, and configured to cause the controllable transmittance film to switch between a first state in which the controllable transmittance film is non-energized and a second state in which the controllable transmittance film is energized. In some of these embodiments, the transparent display panel is positioned between the controllable transmittance film and the clear panel. In some of these embodiments, the clear panel is positioned between the transparent display panel and the touch sensitive overlay. In some of these embodiments, the apparatus is positioned on a vending machine. In some of these embodiments, the apparatus is positioned on a refrigerator.

### CROSS-REFERENCE TO RELATED APPLICATION

This application claims the benefit of U.S. Provisional Patent Application No. 62/940,825, filed Nov. 26, 2019, which is hereby incorporated by reference herein in its entirety.

### TECHNICAL FIELD

The disclosed subject matter relates to see-through, touch-sensitive displays.

### BACKGROUND

Touch-sensitive displays (also referred to as touch screens) are useful interfaces for receiving input from people to systems, such as vending machines, smart appliances, and other hardware-processor-controlled devices.

Sometimes it is desirable to view one or more objects on the opposite side of a panel, wall, surface, etc. on which a touch-sensitive display is mounted. Such a view can be provided by using a window mounted in the panel, wall, surface, etc., but such a window limits the available space that can be used by the touch-sensitive display.

Accordingly, it is desirable to provide see-through, touch-sensitive displays.

### SUMMARY

In accordance with some embodiments, see-through, touch-sensitive displays are provided. More particularly, in some embodiments, apparatuses are provided, comprising: a controllable transmittance film; a transparent display panel; a clear panel; a touch sensitive overlay; and a hardware processor coupled to the controllable transmittance film, the transparent display panel, and the touch sensitive overlay, and configured to cause the controllable transmittance film to switch between a first state in which the controllable transmittance film is non-energized and a second state in which the controllable transmittance film is energized. In some of these embodiments, the transparent display panel is positioned between the controllable transmittance film and the clear panel. In some of these embodiments, the clear panel is positioned between the transparent display panel and the touch sensitive overlay. In some of these embodiments, the apparatus is positioned on a vending machine. In some of these embodiments, the apparatus is positioned on a refrigerator. In some of these embodiments, when in the first state, the controllable transmittance film is translucent. In some of these embodiments, when in the first state, the controllable transmittance film has a transmittance of less than 20%. In some of these embodiments, when in the second state, the controllable transmittance film is transparent. In some of these embodiments, when in the second state, the controllable transmittance film has a transmittance of more than 60%. In some of these embodiments, when in the first state, a voltage across two sides of the controllable transmittance film is less than 10 volts. In some of these embodiments, when in the second state, a voltage across two sides of the controllable transmittance film is greater than 20 volts. In some of these embodiments, the transparent display panel is a transparent liquid crystal display (TLCD) panel. In some of these embodiments, the transparent display panel is an organic light-emitting diode (OLED) display panel. In some of these embodiments, the controllable transmittance film is polymer dispersed liquid crystal (PDLC) film. In some of these embodiments, the controllable transmittance film is nematic curvilinear aligned phase (NCAP) film. In some of these embodiments, the controllable transmittance film is non-linear polymer dispersed liquid crystal display (NPD-LCD) film. In some of these embodiments, the clear panel is tempered glass. In some of these embodiments, the clear panel is plastic.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an example of a touch screen display in a first state in accordance with some embodiments of the disclosed subject matter.

FIG. 2 shows an example of a touch screen display in a second state in accordance with some embodiments of the disclosed subject matter.

FIG. 3 shows a detailed example of hardware that can be used to control components of a touch screen in accordance with some embodiments of the disclosed subject matter.

### DETAILED DESCRIPTION

In accordance with various embodiments, see-through, touch-sensitive displays are provided.

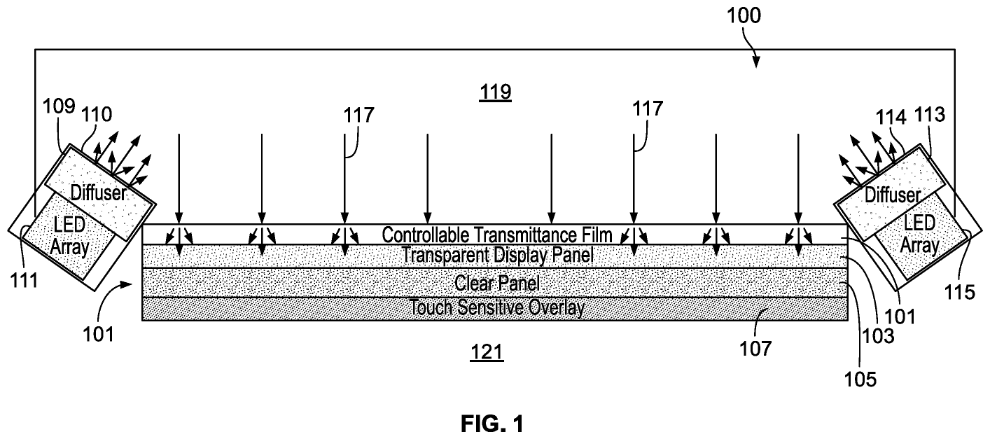

FIG. 1 shows illustrative Apparatus 10. Apparatus 10 may include features that enable Apparatus 10 to function as a touch screen, in a first state, and, in a second state, as a transparent medium.

Apparatus 10 may include layers 101, 103, 105 and 107, in some embodiments.

Layer 101 may be a controllable transmittance film. For example, in some embodiments, layer 101 may use any suitable liquid crystal (LC) or liquid crystal microdroplet display (LCMD) technology to provide a controllable transmittance film. More particularly, for example, in some embodiments, layer 101 may be a polymer dispersed liquid crystal (“PDLC”) film in some embodiments. The PDLC film may be any suitable PDLC film in some embodiments. For example, in some embodiments, the PDLC film may be POLYVISION PDLC film available from Polytronix, Inc. of Richardson, Tex. As other more particular examples, in some embodiments, layer 101 may be a nematic curvilinear aligned phase (NCAP) film and/or a non-linear polymer dispersed liquid crystal display (NPD-LCD) film.

Layer 103 may be a transparent display panel in some embodiments. For example, layer 103 may be a transparent liquid crystal display (“TLCD”) and/or an organic light-emitting diode (OLED) panel in some embodiments. In some embodiments, the layer 103 can be used to display any suitable video content, such as data, image, video, options, information, or any other suitable material that can be presented on a display. The layer 103 may be any suitable panel, such as one suitable for use in a television or a computer in some embodiments. More particularly, for example, in some embodiments, the layer 103 may be Samsung part number BN07-00027A available from Samsung Group of Seoul, South Korea.

Layer 105 may be a clear panel or any suitable see-through material that can be used to provide support to layers 101, 103, and 107. For example, in some embodiments, the clear panel can be any suitable glass, such as tempered glass, in some embodiments. The tempered glass can be any suitable tempered glass in some embodiments. As another example, in some embodiments, the clear panel can be any suitable plastic, such as clear plastic, in some embodiments.

Layer 107 may be a touch sensitive overlay in some embodiments. For example, layer 107 may be a projected capacitive touch screen (“PCAP”) overlay in some embodiments. The PCAP overlay can be any suitable PCAP overlay in some embodiments. For example, in some embodiments, the PCAP overlay can be 3M TOUCH SYSTEMS part number 98-1100-0673-5 available from 3M of St. Paul, Minn. In some embodiments, touch sensitive overlay can use any suitable technologies for detecting a person's touch, such as resistive technologies, capacitive technologies, inductive technologies, temperature sensitive (e.g., infrared) technologies, acoustic technologies, vibration technologies, accelerometer technologies, etc.

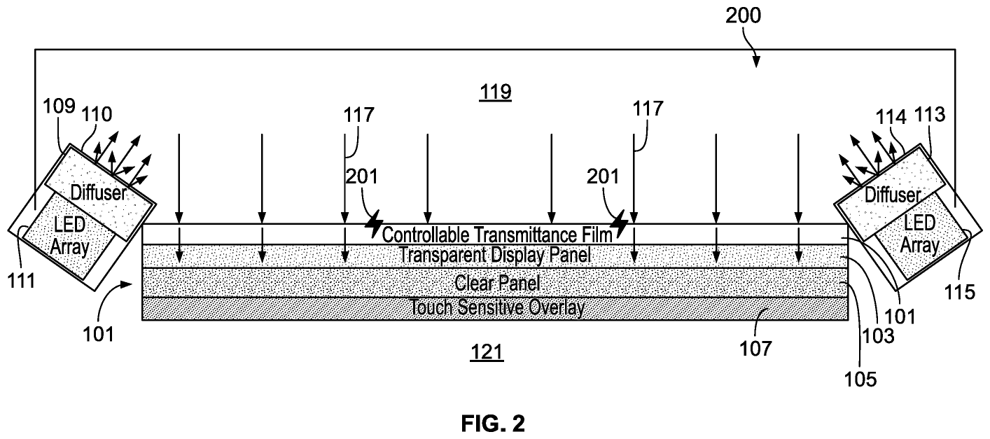

Apparatus 10 may include additional layers (not illustrated), such as one or more additional layers 105, in some embodiments. Apparatus 10 may include layers 101, 103, 105, and 107 in an order different from the order illustrated in FIGS. 1 and 2.

Apparatus 10 may be positioned on a device. The device may be a vending assembly, billboard, information station, a refrigerator, or any other suitable device.

Area 119 may be an area on a first side of Apparatus 10. Area 121 may be an area on a second side of apparatus 121. A user interacting with Apparatus 10 may be in Area 121. A user interacting with Apparatus 10 may be in Area 119 or in Area 121.

In some embodiments when the device is a vending assembly, Area 121 may be an area in front of the vending assembly and area 119 may be an area inside the vending assembly.

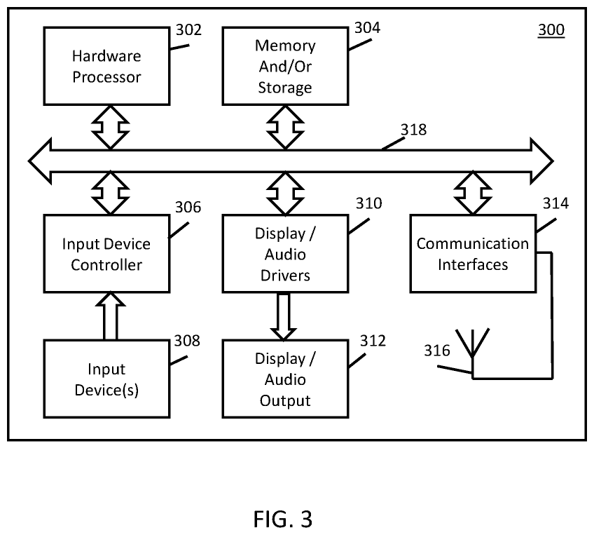

Apparatus 10 may include any suitable light source(s) 110 and/or 114 for illuminating Area 119. In some embodiments, any suitable technology for illuminating Area 119 can be used in some embodiments. For example, in some embodiments, light source 110 may include an include LED Array 111 and Diffuser 109. As another example, in some embodiments, light source 114 may include LED Array 115 and Diffuser 113. The device on which Apparatus 10 is positioned may include light source 110. The device on which Apparatus 10 is positioned may include light source 114. In some embodiments, the light source(s) for illuminating Area 119 can be incandescent rather than LED. In some embodiments, any suitable color of visible light can be used to illuminate Area 119. In some embodiments, any one or more of the light sources used to illuminate Area 119 can be turned on or off at any suitable time for any suitable purpose under the control of a hardware processor, such as the hardware processor described below in connection with FIG. 3.

The light source(s) may be embedded on, or positioned adjacent to, Apparatus 10. The light source(s) may be positioned on the device.

FIG. 1 shows Apparatus 10 in illustrative first state 100. In first state 100, Apparatus 10 may function as a touch screen. In first state 100, images may be displayed on the transparent display panel and may be selectable via the touch sensitive overlay.

In first state 100, the controllable transmittance film forming layer 101 may be non-energized. In first state 100, light 117 traveling from Area 119, towards Area 121, may be diffused by layer 101. Thus, in some embodiments, in first state 100, Area 119 may not be visible to a person viewing from area 121. In some embodiments, the layer 101 may be translucent. More particularly, for example, layer 101 may have a transmittance of less than 20% when in the first state. In some embodiments, a voltage across two sides of the controllable transmittance film may be less than 10 volts.

In first state 100, diffused light 117 may be reflected off surfaces behind the screen. The light may be further diffused by the layer 101. This may create even back-lighting for pixels on the transparent display panel.

FIG. 2 shows Apparatus 10 in illustrative second state 200. In second state 200, Apparatus 10 may be a transparent medium.

In second state 200, the controllable transmittance film in Layer 101 may be energized. Energy symbols 201 may represent the energizing of the controllable transmittance film in Layer 101. In second state 200, light 117 traveling from Area 119, towards Area 121, may travel through Apparatus 10. Thus, in some embodiments, in second state 200, Apparatus 10 may become transparent, and Area 119 behind the controllable transmittance film may be visible to a person viewing from Area 121. More particularly, for example, layer 101 may have a transmittance of greater than 60% in the second state. In some embodiments, a voltage across two sides of the controllable transmittance film may be greater than 20 volts.

In embodiments when Apparatus 10 is positioned on an outer face of a device defining an enclosed inner space, energizing Layer 101 may allow a customer in Area 121 to view an Area 119 behind Apparatus 10 and inside the device's enclosed inner space.

In some embodiments, upon energizing the controllable transmittance film and illuminating Area 119 with any suitable light sources, Area 119 may be visible.

Apparatus 10 may include functionalities for supporting direct lighting, indirect lighting, and special lighting effects.

Apparatus 10 may be used to display computer-generated animations and graphics.

Apparatus and methods may include Apparatus 10 being positioned on an outer face, such as a façade, of a vending assembly. The outer face may be a face that a customer interacts with to purchase an item in the vending assembly. Area 121 may be an area in front of the vending assembly. Area 119 may be an area inside of the vending assembly. Area 119 may be an area in the vending assembly where dispensing of an item occurs.

Methods may include setting Layer 101 to a non-energized state when Apparatus 10 is not dispensing an item. Methods may include a user inputting a user selection on Apparatus 10 to dispense an item. Methods may include a user inputting a user selection on Apparatus 10 to dispense an item when Layer 101 is in a non-energized state.

Methods may include energizing layer 101 when Apparatus 10 is dispensing the requested item. Methods may include energizing Layer 101 during the dispensing to allow the customer to view the dispensing of the requested item in Area 119.

In some embodiments, Apparatus 10 can be controlled using any suitable general-purpose computer or special purpose computer. For example, a vending machine can be implemented using a special purpose computer. Any such general-purpose computer or special purpose computer can include any suitable hardware. For example, as illustrated in example hardware 300 of FIG. 3, such hardware can include hardware processor 302, memory and/or storage 304, an input device controller 306, an input device 308, display/audio drivers 310, display and audio output circuitry 312, communication interface(s) 314, an antenna 316, and a bus 318.

Hardware processor 302 can include any suitable hardware processor, such as a microprocessor, a micro-controller, digital signal processor(s), dedicated logic, and/or any other suitable circuitry for controlling the functioning of a general-purpose computer or a special purpose computer in some embodiments.

Memory and/or storage 304 can be any suitable memory and/or storage for storing programs, data, and/or any other suitable information in some embodiments. For example, memory and/or storage 304 can include random access memory, read-only memory, flash memory, hard disk storage, optical media, and/or any other suitable memory.

Input device controller 306 can be any suitable circuitry for controlling and receiving input from one or more input devices 308 in some embodiments. For example, input device controller 306 can be circuitry for receiving input from a touch sensitive overlay in Layer 107, from a touchscreen, from a keyboard, from one or more buttons, from a voice recognition circuit, from a microphone, from a camera, from an optical sensor, from an accelerometer, from a temperature sensor, from a near field sensor, from a pressure sensor, from an encoder, and/or any other type of input device.

Display/audio drivers 310 can be any suitable circuitry for controlling and driving output to one or more display/audio output devices 312 in some embodiments. For example, display/audio drivers 310 can be circuitry for driving a controllable transmittance film in Layer 101, a transparent display panel in Layer 103, light source(s) 110 and/or 114 (and/or any other suitable light sources), a touchscreen, a flat-panel display, a projector, a speaker or speakers, and/or any other suitable display and/or presentation devices.

Communication interface(s) 314 can be any suitable circuitry for interfacing with one or more communication networks. For example, interface(s) 314 can include network interface card circuitry, wireless communication circuitry, and/or any other suitable type of communication network circuitry.

Antenna 316 can be any suitable one or more antennas for wirelessly communicating with a communication network in some embodiments. In some embodiments, antenna 316 can be omitted.

Bus 318 can be any suitable mechanism for communicating between two or more components 302, 304, 306, 310, and 314 in some embodiments.

Any other suitable components can be included in hardware 300 in accordance with some embodiments.

In some embodiments, any suitable computer readable media can be used for storing instructions for performing controlling whether Apparatus 10 is in first state 1 or second state 2 as described herein. For example, in some embodiments, computer readable media can be transitory or non-transitory. For example, non-transitory computer readable media can include media such as non-transitory forms of magnetic media (such as hard disks, floppy disks, and/or any other suitable magnetic media), non-transitory forms of optical media (such as compact discs, digital video discs, Blu-ray discs, and/or any other suitable optical media), non-transitory forms of semiconductor media (such as flash memory, electrically programmable read-only memory (EPROM), electrically erasable programmable read-only memory (EEPROM), and/or any other suitable semiconductor media), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Although the invention has been described and illustrated in the foregoing illustrative embodiments, it is understood that the present disclosure has been made only by way of example, and that numerous changes in the details of implementation of the invention can be made without departing from the spirit and scope of the invention, which is limited only by the claims that follow. Features of the disclosed embodiments can be combined and rearranged in various ways.

What is claimed is:

1. An apparatus comprising:
a controllable transmittance film;
a transparent display panel;
a clear panel;
a touch sensitive overlay; and
a hardware processor coupled to the controllable transmittance film, the transparent display panel, and the touch sensitive overlay, and configured to cause the controllable transmittance film to switch between a first state in which the controllable transmittance film is non-energized and a second state in which the controllable transmittance film is energized.

2. The apparatus of claim 1, wherein the transparent display panel is positioned between the controllable transmittance film and the clear panel.

3. The apparatus of claim 2, wherein the clear panel is positioned between the transparent display panel and the touch sensitive overlay.

4. The apparatus of claim 1, wherein the apparatus is positioned on a vending machine.

5. The apparatus of claim 1, wherein the apparatus is positioned on a refrigerator.

6. The apparatus of claim 1, wherein, when in the first state, the controllable transmittance film is translucent.

7. The apparatus of claim 6, wherein, when in the first state, the controllable transmittance film has a transmittance of less than 20%.

8. The apparatus of claim 1, wherein, when in the second state, the controllable transmittance film is transparent.

9. The apparatus of claim 8, wherein, when in the second state, the controllable transmittance film has a transmittance of more than 60%.

10. The apparatus of claim 1, wherein, when in the first state, a voltage across two sides of the controllable transmittance film is less than 10 volts.

11. The apparatus of claim 1, wherein, when in the second state, a voltage across two sides of the controllable transmittance film is greater than 20 volts.

12. The apparatus of claim 1, wherein the transparent display panel is a transparent liquid crystal display (TLCD) panel.

13. The apparatus of claim 1, wherein the transparent display panel is an organic light-emitting diode (OLED) display panel.

14. The apparatus of claim 1, wherein the controllable transmittance film is polymer dispersed liquid crystal (PDLC) film.

15. The apparatus of claim 1, wherein the controllable transmittance film is nematic curvilinear aligned phase (NCAP) film.

16. The apparatus of claim 1, wherein the controllable transmittance film is non-linear polymer dispersed liquid crystal display (NPD-LCD) film.

17. The apparatus of claim 1, wherein the clear panel is tempered glass.

18. The apparatus of claim 1, wherein the clear panel is plastic.
